(19) United States
(12) Patent Application Publication
(10) Pub. No.: US 2022/0109282 A1
(43) Pub. Date: Apr. 7, 2022

(54) METHOD FOR OBTAINING ELECTRONIC DEVICES AND ELECTRONIC DEVICES

(71) Applicant: OSRAM Opto Semiconductors GmbH, Regensburg (DE)

(72) Inventors: Markus BOSS, Regensburg (DE); Chai Liang LOKE, Gelugor (PG) (MY); Zeljko PAJKIC, Regensburg (DE); Wan Leng LIM, Penang (MY)

(21) Appl. No.: 17/423,209

(22) PCT Filed: Jan. 17, 2019
(86) PCT No.: PCT/EP2019/051192

§ 371 Date: Jul. 15, 2021

(51) Int. Cl. H01S 5/02315; H01S 5/02

(52) U.S. Cl. CPC H01S 5/02315; H01S 5/183; H01S 5/0201

(57) ABSTRACT

The invention refers to electronic devices (D) and to a method for obtaining electronic devices (D) comprising, electronic elements, in particular optoelectronic elements (7), the method comprising the steps of:—providing (S1) a substrate from which first walls (1) protrude along a Z-axis towards an open end side forming at least one rectangle along a X-Y-plane surrounding a respective at least one space(S);—positioning (S2) a respective electronic element (7a), in particular optoelectronic element (7),within the respective space(S)and connecting it to contact pads (9);—attaching (S3) a respective functional element (11a), in particular optical element (11), in particular a lens, at the open end side of respective first wall (1) to cover the respective space (S);—forming a second wall (2) by surrounding (S4) the respective functional element (11a), in particular optical element (11), with a darn material.

### CROSS-REFERENCE TO RELATED APPLICATIONS

This patent application is a national stage entry from International Application No. PCT/EP2019/051192, filed on Jan. 17, 2019, published as International Publication No. WO 2020/147958 A1 on Jul. 23, 2020, the entire contents of all of which are incorporated by reference herein.

### FIELD

The present invention relates to a method for manufacturing or obtaining electronic devices and to such electronic device.

### BACKGROUND

Complexity of the process with the current design of vertical cavity surface emitting laser (VCSEL) having a two-piece design with two processes, one of a meta-lens attach and second of a frame attach, results in a high time-consumption, higher investment and higher risk of delamination. Besides, the whole package involves several materials which would potentially induce stress in it. The invention refers to the reliable manufacturing of robust electronic devices, in particular optoelectronic devices, with deep cavities and with high walls, respectively.

Walls and thereto related cavities in electronic devices, in particular in electro-optical devices, and around the devices are necessary for a variety of reasons:

Lateral mechanical protection of sensitive optoelectronic components is a reason. This is especially crucial with specific components having certain dimensions like meta-lenses and with applications, in which mechanical stability is critical, like for example laser packages because of eye-safety requirements. Another reason for applying walls is the prevention of so-called cross-talks between neighboring components like emitters or detectors.

A known solution comprises more components e.g. using a flat substrate like for example PCB (printed copper board) or ceramic in combination with a frame in which the walls are provided. This solution is mechanical less robust. With several components in particular the lateral separation of these components is critical.

Another known component applicable is a so called Quad-Flat-No-Leads-substrate. The limitation of this stated solution is the limited height of the QFN-walls. There may be issues in the manufacture with increasing height. Moreover, with increasing height the size of the package in the X-Y-plane must increase due to the deforming bevels in the Z-direction and because of the minimum wall thickness of the packages. It is challenging to reliably provide processes like die bonding or wire bonding in a resulting deep cavity.

It is therefore an object of the invention to provide robust electronic devices, in particular optoelectronic devices, having die cavities comprising high walls. The invention concerns in particular the obtaining of vertical-cavity-surface-emitting lasers (VCSEL). Optoelectronic devices comprising optical elements like lenses should be obtained easily, within a short time period, at low costs having low risk of delamination and low material induced stress.

The object is solved by a method for obtaining of electronic devices according to the main claim and a corresponding method for obtaining optoelectronic devices and the correspondingly obtained electronic devices or optoelectronic devices.

### SUMMARY

According to one aspect of the invention, a method for obtaining electronic devices, in particular optoelectronic devices, in particular VCSEL, provided by packages comprising the following steps is suggested,
providing a substrate from which a first wall protrude along a Z-axis towards an open end side forming at least one rectangle along a X-Y-plane surrounding at least one space;
positioning a respective electronic element, in particular optoelectronic element, within a respective space and connecting the electronic element to contact pads;
arranging a respective functional element, in particular optical element, in particular a lens, at the open end side of the first wall to cover a respective space;
forming a second wall by surrounding the respective functional element, in particular optical element, along a X-Y-plane with a dam material.

Methods for obtaining common electronic devices and these electronic devices themselves are covered by the invention. For example settings of distances between an electronic element and a common cover or an alternative functional layer are included into the scope. Intended distance settings could be also performed because of thermal or mechanical reasons for example.

According to one aspect of the invention one solution for a whole package is considered which could solve the potential stress, delamination and planar placement of the optical element attachment.

Further advantages of the invention are simple assembly processes, lower risk of delamination, in particular of meta-lenses, single material sawing which means sawing of a metal lead frame only, which prevents delamination of used thixotropic material during assembly as it is not sawn. Another aspect are lower investment costs, the material will not smear and contaminate the structured lens area. Double enhancement of the adhesion of lenses, in particular meta-lenses, improve planarity of the lens respectively meta-lens placement.

Further aspects of the invention are stated by the sub-claims.

According to an aspect of the invention the substrate can be a Quad-Flat-No-Leads-QFN leadframe. An electronic device or package provided with the above method comprising high walls, and/or deep cavities, respectively can be reliably assembled. In a QFN, the risk of molding deep cavities is omitted. The size of a package in the X-Y-plane can be reduced compared to conventional solutions. This is because the necessity for the deforming bevel or thicker walls can be omitted.

In another aspect, pre-molding of the substrate can be performed. Additionally molding of a polymer compound material for constructing walls and cavities, respectively, is possible.

In another aspect the leadframe can be etched on both sides. Thus a variety of structures can be provided by the leadframe. Accordingly resulting devices can become compact.

According to another aspect of the invention the dam material can be a thixotropic material, in particular a high thixotropic material, in particular silicone and/or epoxy. Thixotropy is a time-dependent shear thinning property.

According to a further aspect forming the second wall can be performed by at least one of casting or molding, compression molding, transfer molding or by film assisted molding of the dam material.

According to a further aspect, the step of forming a first wall can comprise forming a recess along the first wall's open end side.

According to a further aspect, before the step of forming a recess the open end side of a first wall could have been formed as a flat area.

According to a further aspect, the step of forming a first wall can comprise forming a rising along the first wall's open end side.

According to a further aspect, a second wall can be provided by filling of the dam material into gaps between adjacent positioned optical elements, recesses and/or risings.

According to a further aspect, the step of forming a second wall can comprise forming of additional structures of the dam material onto a surface of an optical element surface that is averted to the substrate.

According to a further aspect, the step of forming a first wall can comprise forming an open end side of a first wall as a flat area, whereby an optical element can be attached flush with a first wall, and a second wall can be formed perpendicular to the substrate by completely surrounding the optical element and the first wall along a X-Y-plane forming rectangles.

According to a further aspect the second wall can be formed in between the optical element, the first wall and a completely surrounding third wall, in particular being pre-molded on the substrate. According to this further aspect, the second walls can be formed within third walls protruding from the substrate along a Z-axis towards an open end side forming in a X-Y-plane at least one rectangle surrounding a respective rectangle formed by the optical element and the first walls.

According to a further aspect first walls can comprise equal thicknesses and rectangles can comprise equal sizes. According to this aspect, the first walls can comprise equal thicknesses and rectangles comprise equal sizes. They may of course have a different shape or dimensions.

According to a further aspect optoelectronic elements can be dies.

According to a further aspect connecting of optoelectronic elements can be performed by wire bonding to contact pads. According to another aspect optoelectronic elements can be connected by wire bonding. Processes like wire bonding or die bonding can be reliably performed in non-deep cavities, before hydride walls are constructed by subsequent steps, like casting. Connecting the optoelectronic elements can be achieved in different way. In some aspects the optoelectronic elements are wire bonded to the contact pads. In an alternative solution, the optoelectronic elements may be flip-chip and/or the contacts of the optoelectronic elements are soldered to the contact pads.

According to a further aspect lenses can be meta-lenses. According to a further aspect dam material can comprise an adhesive.

According to a further aspect a step of separating electronic packages out of a row or out of an array of packages can be performed.

According to another aspect a step of separating packages can comprise sawing.

Another aspect relates to a device comprising, electronic elements, in particular optoelectronic elements. Such device may comprise
a substrate from which first walls protrude along a Z-axis towards an open end side forming at least one rectangle along a X-Y-plane surrounding at least space;
a respective optoelectronic element within a respective space being connected to contact pads;
a respective optical element, in particular a lens, at the open end side of the first wall covering a respective space;
whereby each optical element is surrounded along a X-Y-plane with a dam material forming second walls.

According to some aspects, the optoelectronic element can comprise an emitter, and can be in particular a LED, a LASER, a VCSEL. Alternatively, or in addition, the optoelectronic element can comprise a detector or sensor.

### BRIEF DESCRIPTION OF THE DRAWINGS

The invention will be described by examples referring to the drawings. The drawings show in

FIG. 1A a known embodiment of an optoelectronic device;

FIG. 1B a cross sectional view of the known embodiment of FIG. 1A;

FIG. 2A a perspective view of an array according to some aspects of the invention;

FIG. 2B a top view of an array according to some aspects of the invention;

FIGS. 3A, 3B, 3C, 3D, 3E, 3F, 3G, 3H, exemplary steps of a method according to a first example of the present invention;

FIGS. 4A, 4B, 4C, 4D, 4E, 4F, 4G, exemplary steps of a method according to a second example of the present invention;

FIGS. 5A, 5B, 5C, 5D, 5E, 5F, exemplary steps of a method according to a third example of the present invention;

FIGS. 6A, 6B, 6C, 6D, 6E, 6F, exemplary steps of a method according to a fourth example of the present invention;

FIG. 7 a step 3 of third and fourth example of the present invention;

FIG. 8 an alternative step 3 of third and fourth example of the present invention;

FIG. 9 a method according to another example of the present invention.

### DETAILED DESCRIPTION

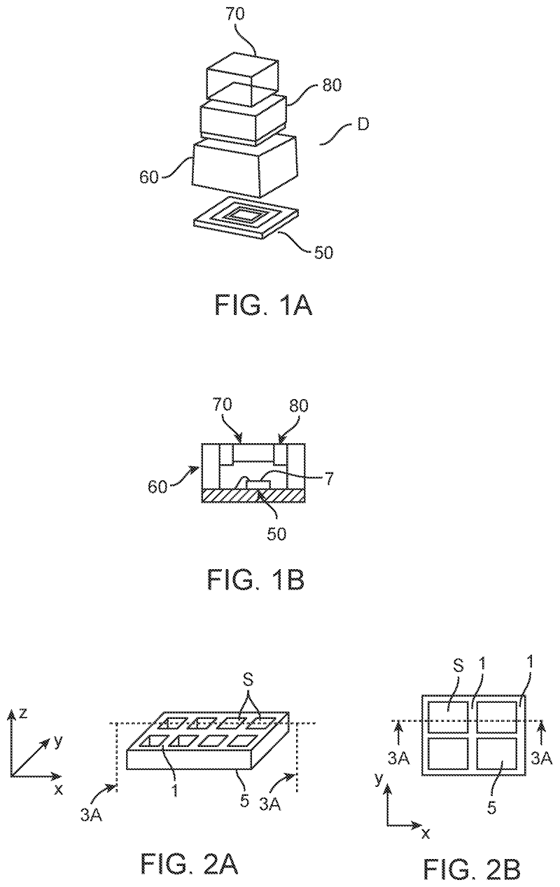

FIG. 1A shows a known embodiment of an optoelectronic device. FIG. 1A shows an existing design of a vertical-cavity-surface-emitting laser. This VCSEL comprises a two piece design with two processes, a meta-lens attach and a frame attach which are time consuming, need a high investment and comprise a higher risk of delamination. Moreover, this shown package involves several materials, which could potentially induce stress in it. 50 is a ceramic, numeral 60 refers to a frame, numeral 70 refers to a meta-lens and numeral 80 refers to a so-called potting area. In electronics, potting is a process of filling a complete electronic assembly with a solid or gelatinous compound for resistance to shock and vibration, and for exclusion of moisture and corrosive agents. Thermosetting plastics or silicone rubber gels are often used. Many sites recommend using silicone or epoxy to protect from impact and loose wires. In the potting process, an electronic assembly is placed inside a mold which is then filled with an insulating liquid compound that hardens, permanently protecting the assembly. The mold is part of the finished article and can provide shielding or heat dissipating functions in addition to acting as a mold. A cast assembly uses a removable mold.

FIG. 1B shows a cross sectional view of the known embodiment of FIG. 1A. FIG. 1B shows an existing design of a VCSEL, whereby 50 is a ceramic, numeral 60 refers to a frame, numeral 70 refers to a meta-lens and numeral 80 refers to the so-called potting area of FIG. 1A. An optoelectronic element 7 is deposited on the ceramic 50 and is electrically connected to contact pads. Lens 70 is attached to the frame 60 via the potting area 80.

FIG. 2A shows a perspective view of an array according to some aspects of the invention. FIG. 2A shows a structured substrate, in particular a Quad-, Flat, No Leads-(QFN)-leadframe 5 with periodically arranged protrusions forming respective spaces S surrounded by first walls 1. FIG. 2A shows a substrate from which first walls 1 protrude along a Z-axis towards an open end side forming eight rectangles along a X-Y-plane surrounding respective eight spaces S. FIG. 2A shows an array of according to this example eight rectangles distributed along a X-Y-plane and creating eight spaces. Rectangles in this application could basically also be squares.

The substrate is a carrier and can be a leadframe, in particular a Quad-, Flat, No Leads-(QFN)-leadframe 5. The substrate can comprise a metal, in particular copper. The leadframe can be a premolded QFN-leadframe, whereby the premolded material can be any known plastic or compound material. Flat no-leads packages such as quad-flat no-leads (QFN) and dual-flat no-leads (DFN) physically and electrically connect integrated circuits to printed circuit boards. Flat no-leads, also known as micro leadframe (MLF) and SON (small-outline no leads), is a surface-mount technology, one of several package technologies that connect ICs (Integrated Circuits) to the surfaces of PCBs (Printed Copper Boards) without through-holes. Flat no-lead is a near chip scale plastic encapsulated package made with a planar copper lead frame substrate. Perimeter lands on the package bottom provide electrical connections to the PCB (Printed Copper Board). Flat no-lead packages include an exposed thermal pad to improve heat transfer out of the IC (Integrated Circuit) (into the PCB). Heat transfer can be further facilitated by metal vias in the thermal pad.

FIG. 2B shows a top view of an array according to some aspects of the invention. The example comprises four rectangles and four spaces S formed by first walls 1 protruding out from a QFN-leadframe 5. In between two adjacent rectangles along an X-Y-plane first walls 1 are formed. Resulting walls of an electronic device package are provided hybrid and can comprise several components. As a starting component for example a QFN-leadframe 5 with a less high first wall 1 could be used. In course of the processing the walls could be further constructed for example by casting. First walls 1 can be enlarged in height for example by casting. The resulting height should be suitable in particular for vertical-cavity-surface-emitting lasers (VCSEL).

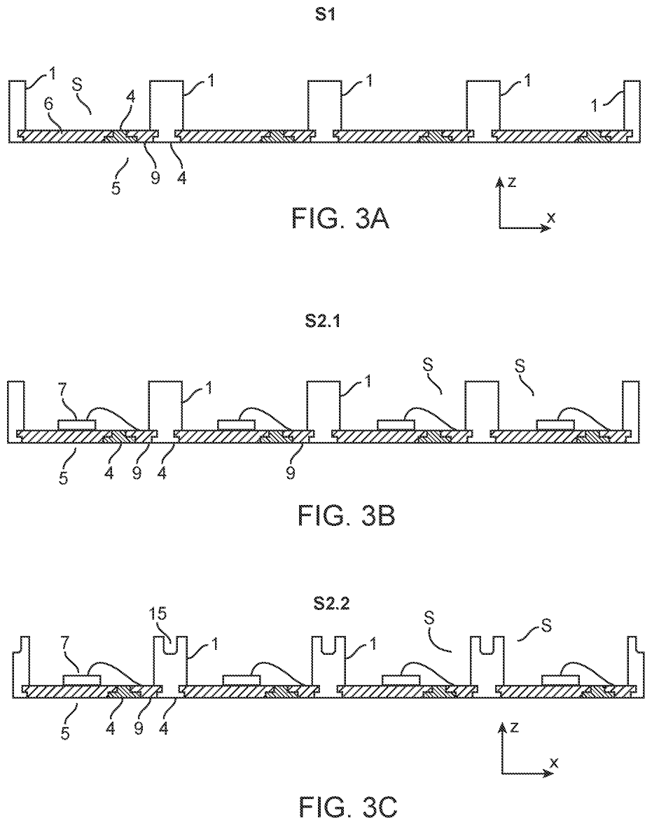

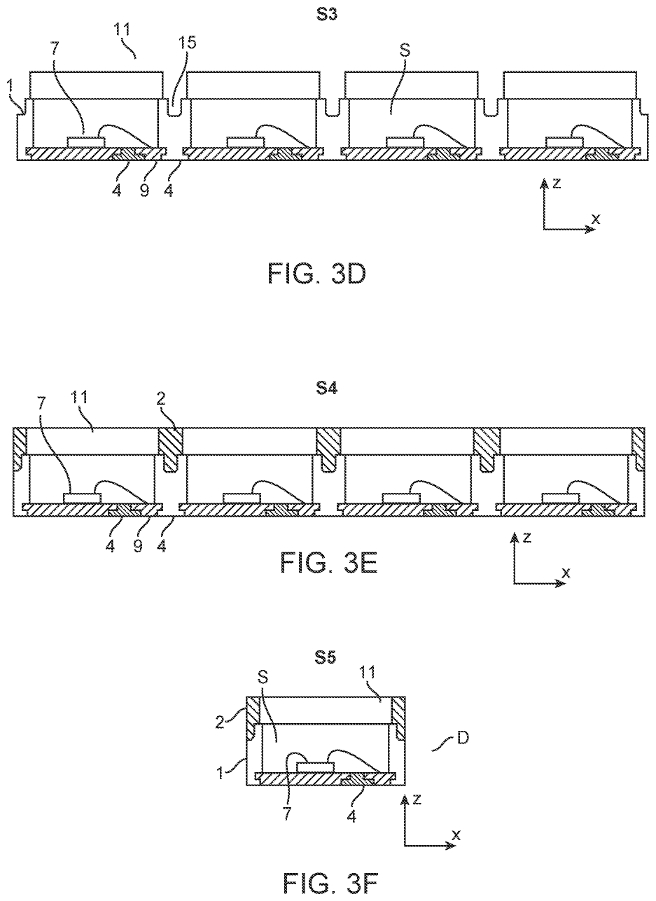

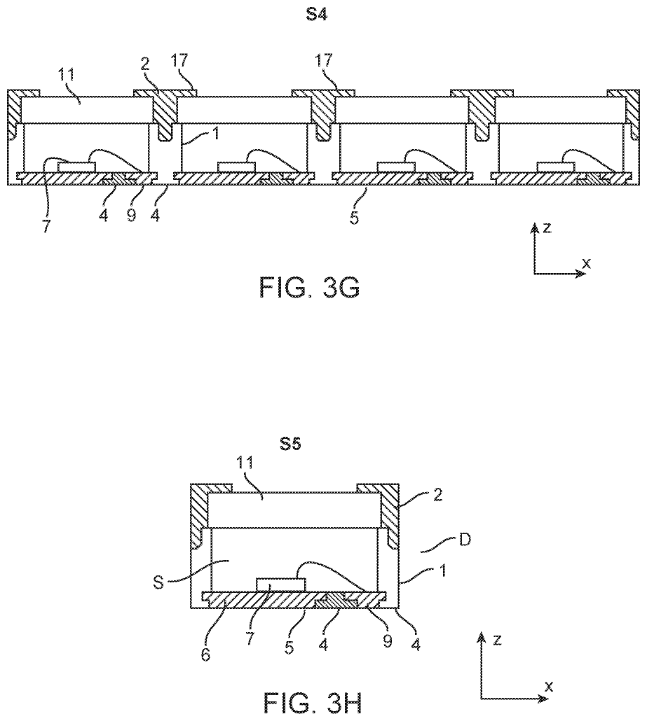

Arrows 3A within FIGS. 2A and 2B show the direction of the cross section of the cross sectional view of FIG. 3A.

FIG. 3A illustrates an exemplary step S1 of a method according to a first example of the present invention. It is a cross sectional view whereby the cutting plane is indicated by arrows 3A in FIG. 2A. FIG. 3A shows a starting QFN-leadframe 5 whose first wall 1 could comprise flat areas at an open end side. FIG. 3A shows a substrate which is provided by a quad-flat-no-leads-QFN leadframe 5. The leadframe 5 could be premolded and could be etched on both sides. Numeral 1 shows in the cross-sectional view the first wall 1 protruding along a Z-axis towards an open end side forming four rectangles along a X-Y-plane surrounding four spaces S. FIG. 3A shows electrically isolating parts 4 in an upside down “T”-shape and contact pads 9. Contact pads 9 are arranged in the leadframe 5 and are separated by the electrically isolating parts 4 and the first wall 1. Contact pads 9 in this example are extending through the leadframe 5. FIG. 3A shows four provided spaces S whereby the left first wall 1 portion and the right first wall 1 portion are ending walls and the other wall 1 portions are intermediate walls.

As previously, the premold leadframe 5 comprises contact pads 9 arranged between isolation parts 4 provided by a filling and by the first wall 1. The two isolation parts 4 extend through the leadframe 5 to prevent short circuit. In this example, the leadframe 5 comprises a metallic heat sink area 6 arranged on a right side of the first wall 1 between the first wall 1 and the isolation part 4 provided by a filling. An optoelectronic element 7 can be placed on the heat sink area 6 and can be contacted to the contact pad 9. Although only a single contact pad 9 is illustrated herein, a skilled person will acknowledge to arrange further contact pads 9 onto the leadframe 5 to achieve the intended amount of the pads.

FIG. 3B shows a further exemplary step S2.1 of a method according to a first example of the present invention. FIG. 3B illustrates a next step of manufacturing whereby respective optoelectronic elements 7 are arranged by die attach on a heat sink area of the lead frame 5 within a respective space S created by the first wall 1. Moreover, the optoelectronic elements 7 are connected to contact pads 9 for example by wire bonding.

Alternative options could be provided by for example flip-chip technology. Instead of optoelectronic elements 7 basically all types of electronic elements 7a could be used for providing devices or performing methods.

In the cutting plane of FIGS. 3A and 3B the profile of the first wall 1 along its open end is flat.

FIG. 3C shows a further exemplary step S2.2 of a method according to a first example of the present invention. FIG. 3C illustrates a step following the step of FIG. 3B. FIG. 3C shows that recesses 15 can be formed into the first wall 1 in case the first wall 1 comprises a flat open end. It is possible to form a recess 15 or a corresponding trench into the first wall 1 for example by dicing.

During this step S2.2 the first wall 1 extends along a X-Z plane from a left surface along its open end side to a right surface comprising a trench or recess 15. Recess 15 is centrally arranged on top of the open end side of first wall 1 and comprises a depth in the range of 10% to 40% of the wall height, in particular 25%. However, other depth for recess 15 can be used as well. The bottom of each recess 15 can be flat or curved. In some cases the surface to recess 15 or to the bottom of recess 15 of first wall 1 may be roughened to improve adhesion of a second material on it.

The recess 15 of first wall 1 forms a structured open end side, which could also be called a cavity. This feature of the first wall 1 is advantageous because it improves the fixing of a second wall 2, thereby forming a hybrid wall. Thus the mechanic stability and reliability of the packages or devices D can be improved.

FIG. 3D shows a further exemplary step of a method according to a first example of the present invention. By this step S3 as illustrated in FIG. 3D, an optical element 11 can be placed at the open end side of the first wall 1 to cover the respective space S, in which the optoelectronic element 7 is arranged. The emission direction of element 7 is towards the optical element 11. The optical element 11 can be a lens or a meta-lens.

According to FIG. 3D first walls 1 comprise recesses 15. Each optical element 11 is arranged flush with remaining flat portions of the open end side of the first wall 1. The arranged optical elements 11 and the first wall 1 comprising recesses 15 create empty spaces and/or gaps in between. Instead of optical elements 11 basically all types of functional elements 11a could be used for providing devices or performing methods.

FIG. 3E shows a further exemplary step of a method according to a first example of the present invention. FIG. 3E shows a step S4 following step S3 of FIG. 3D. Accordingly, a second wall 2 can be formed by surrounding a respective optical element 11 along a X-Y-plane with a dam material. Accordingly the second wall 2 may be formed into empty spaces and/or gaps between adjacent optical elements 11 and recesses 15.

FIG. 3F shows a further exemplary step of a method according to a first example of the present invention. FIG. 3F shows the separation of a single electronic package out of a row or out of an array of finished packages. Each finished package provides an electronic device D. A starting base for the row or array of finished packages are the arrays of FIGS. 2A and 2B. According to FIG. 3F the obtained electronic device D comprises enough height of first wall 1 together with second wall 2. The distance between optoelectronic element 7 and optical element 11 can be set according to the intended operation of the electronic device D. Moreover first wall 1, optical element 11 and leadframe 5 together can seal the space S to protect the electrically connected optoelectronic element 7. The separation can be performed for example by sawing, in particular by respectively dividing first wall 1 and second wall 2 into two halves along an Y-Z-plane.

FIG. 3G shows a further exemplary step of a method according to a first example of the present invention. In contrast to FIG. 3E this FIG. 3G shows a step S4 whereby the implemented second wall 2 additionally forms structures 17 on surfaces of the optical elements 11 whereby these surfaces are averted to the leadframe 5. The second wall 2 creates a wrap-around of each optical element 11.

FIG. 3H shows a further exemplary step of a method according to a first example of the present invention. FIG. 3H shows a singulated electronic device D which was separated out of an array or row of packages for example like the one of FIG. 3G. Each finished package provides an electronic device D. A starting base for the row or array of finished packages are the arrays of FIGS. 2A and 2B. According to FIG. 3H the obtained electronic device D comprises the correct height of first wall together with second wall 2. The distance between optoelectronic element 7 and optical element 11 can be set according to the intended operation of the electronic device D. Moreover first wall 1, optical element 11 and leadframe 5 together can seal the space S to protect the electrically connected optoelectronic element 7. The separation can be performed for example by sawing, in particular by respectively dividing first wall 1 and second wall 2 into two halves along an Y-Z-plane.

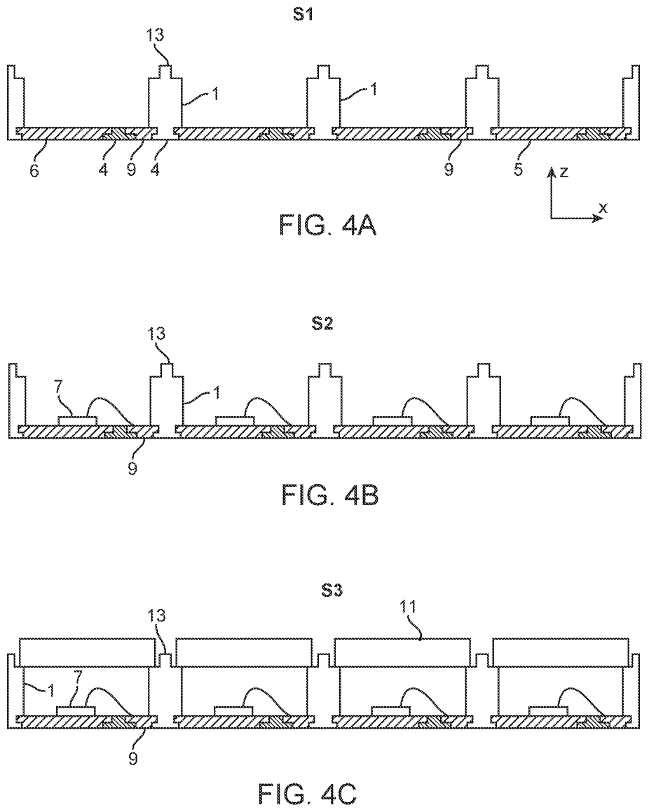

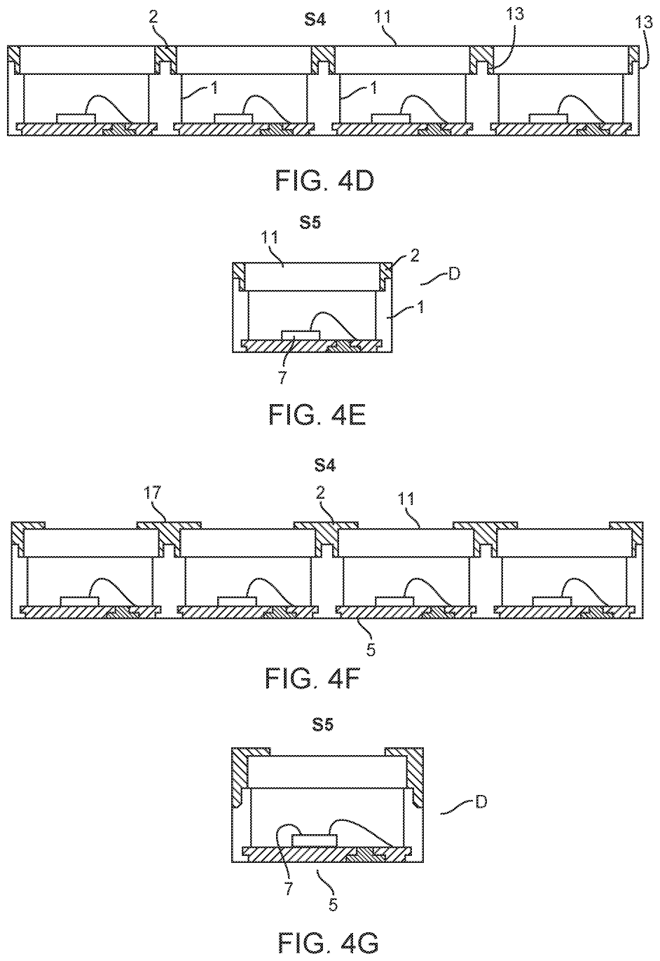

FIG. 4A shows an exemplary step S1 of a method according to a second example of the present invention. FIG. 4A shows another embodiment of a premold leadframe 5 comprising a first wall 1. As previously, the premold leadframe 5 comprises contact pads 9 arranged between isolation parts 4 provided by a filling and by the first wall 1. The two isolation parts 4 extend through the leadframe 5 to prevent short circuit. In this example, the leadframe 5 comprises a metallic heat sink area 6 arranged on a right side of the first wall 1 between the first wall 1 and the isolation part 4 provided by a filling. An optoelectronic element 7 can be placed on the heat sink area 6 and can be contacted to the contact pad 9. Although only a single contact pad 9 is illustrated herein, a skilled person will acknowledge to arrange further contact pads 9 onto the leadframe 5 to achieve the intended amount of the pads.

During this first step S1 the first wall 1 extends along a X-Z plane from a left surface along its open end side to a right surface comprising a protrusion or rising 13. Rising 13 is centrally arranged on top of the open end side of first wall 1 and comprises a height in the range of 10% to 40% of the wall height, in particular 25%. However, other height for rising 13 can be used as well. The top of each rising 13 is flat. In some cases the surface to rising 13 or to the top of first wall 1 may be roughened to improve adhesion of a second material and/or a lens on it.

The protrusion or rising 13 of first wall 1 forms a structured open end side, which could also be called a cavity rim. This feature of the first wall 1 is advantageous because it improves the fixing of a second wall 2, thereby forming a hybrid wall. Thus the mechanic stability and reliability of the packages or devices D can be improved.

FIG. 4B shows an exemplary step S2 of a method according to a second example of the present invention. FIG. 4B shows another embodiment of first wall 1, here in this case comprising a rising 13 in its profile between a left surface and a right surface along its open end side.

FIG. 4C shows an exemplary step S3 of a method according to a second example of the present invention. FIG. 4C shows another embodiment which is similar to the embodiment of FIG. 3D but here the first walls 1 comprise risings 13. Between the first walls 1 and the optical elements 11 are gaps or empty spaces, being different in shape in comparison to FIG. 3D.

FIG. 4D shows an exemplary step S4 of a method according to a second example of the present invention. FIG. 4D shows the embodiment of the first wall 1 comprising a rising 13. The before mentioned gaps or empty spaces can be filled with dam material by casting or molding. Thus second walls 2 can be constructed by casting or by compression molding or by transfer molding or by film-assistant molding. Thus, first walls 1 and second walls 2 can be provided together creating a hybrid wall. The material could be for example silicone or on a basis of epoxy. The hybrid wall comprises first wall 1 and second wall 2. The hybrid wall can be provided as a sidewall or an intermediate wall for example in a multi-cavity package.

FIG. 4E shows an exemplary step S5 of a method according to a second example of the present invention. FIG. 4E shows a scattered optical device D, respectively package, whereby first walls 1 and second walls 2 carry the optical element 11 and all the outer surfaces where flush with each other. The optoelectronic element 7 can be protected.

FIG. 4F shows an exemplary step S4 of a method according to a second example of the present invention. FIG. 4F shows the embodiment of FIG. 4D additionally comprising additional structures 17 along the sides of the optical elements 11 averted to the leadframe 5.

FIG. 4G shows an exemplary step S5 of a method according to a second example of the present invention. FIG. 4G shows a scattered optical device D or package resulting from an array or row according to FIG. 4F. An optoelectronic device can include no, one or several emitters and could be a LED, a laser, a VCSEL . . . An optoelectronic device can comprise no, one or several detectors or sensors.

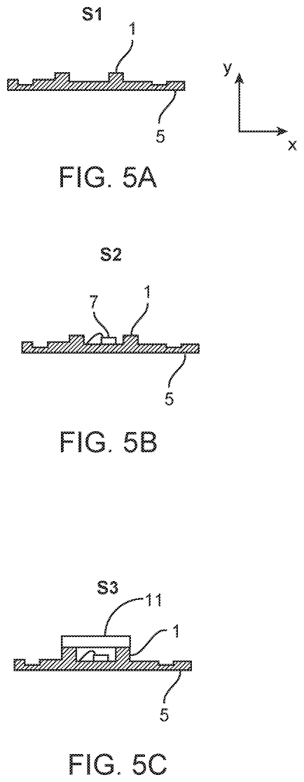

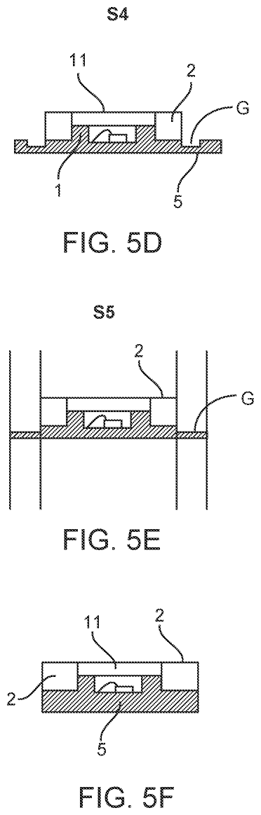

FIG. 5A shows a further exemplary step S1 of a method according to a third example of the present invention. FIG. 5A shows another embodiment of a substrate 5 in a cross-sectional view.

First wall 1 are arranged on the substrate and protrude in Z-direction forming an open end side. FIG. 5A shows a premold QFN substrate with a groove and lens holder formed by the first wall 1.

FIG. 5B shows a further exemplary step S2 of a method according to a third example of the present invention. FIG. 5B shows a manufacturing stage of S2 where a VCSEL chip is attached inside a first wall 1 serving as a lens holder. Accordingly, wires can be bonded.

FIG. 5C shows a further exemplary step S3 of a method according to a third example of the present invention. FIG. 5C shows another embodiment of the manufacturing stage of step S3. Here an optical element 11 is completely positioned on first wall 1, whereby a respective outside surface of the optical element 11 is flush with the outside surfaces of the first wall 1. According to this figure, a meta-lens is attached on the lens holder provided by the first wall 1 to create an air gap surrounding the VCSEL chip to have more accurate meta-lens placements.

FIG. 5D shows a further exemplary step S4 of a method according to a third example of the present invention. FIG. 5D shows the step of providing a second wall 2. A high thixotropic dam material (silicone, epoxy) is dispensed at both outer sides of the lens holder wall 1. An outside groove G will function as to contain any excessive flow of dam material as well as acting as “line mark” as indication of the dispensing region. The high-thixotropic material comprises an added adhesive to hold the lens 11.

FIG. 5E shows a further exemplary step S5 of a method according to a third example of the present invention. FIG. 5E shows the singulation of each of the units out of an array or from a panel or row. A cutting area is marked by the vertical lines in FIG. 5E.

FIG. 5F shows a further exemplary step of a method according to a third example of the present invention. FIG. 5F shows a final optoelectronic device D or final optoelectronic package.

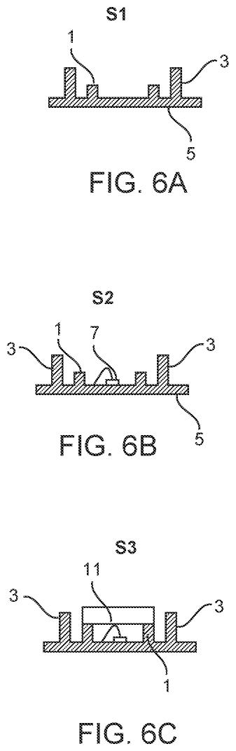

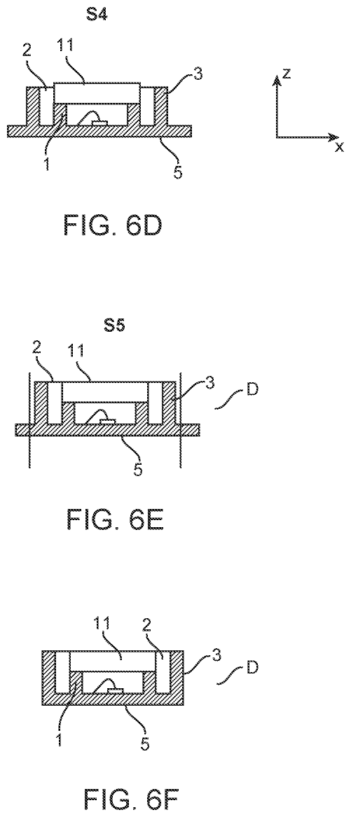

FIG. 6A shows a further exemplary step S1 of a method according to a fourth example of the present invention. FIG. 6A shows another example concerning the same concept and principle. By this step S1 the leadframe 5 is premolded with a barrier and a lens holder wall for each unit. Numeral 1 refers to a first wall or lens holder wall. Numeral 3 refers to a third wall or barrier.

FIG. 6B shows a further exemplary step S2 of a method according to a fourth example of the present invention. FIG. 6B is a cross-sectional view of the example where a VCSEL chip 7 is attached inside first wall 1 (lens holder) and inside third wall 3 (barrier). A wire to an optoelectronic element 7 can then be bonded.

FIG. 6C shows a further exemplary step S3 of a method according to a fourth example of the present invention. FIG. 6C is similar to FIG. 5C but here the third wall 3 is formed. Moreover, here a meta-lens 11 is attached on the first wall 1 (lens holder) provided by the first wall 1 to create an air gap surrounding the VCSEL chip to have more accurate meta-lens placements with the first wall 1 (lens holder) as an indicator.

FIG. 6D shows a further exemplary step S4 of a method according to a fourth example of the present invention. FIG. 6D shows the example with an additional third wall 3. The second wall 2 is formed within the third wall 3 protruding from the substrate 5 along a Z-axis towards an open end side forming in a X-Y-plane at least one rectangle surrounding a respective rectangle formed by the optical element 11 and the first wall 1. High-thixotropic dam material, for example silicone or epoxy, is here dispensed in between the barrier provided by third wall 3 and lens holder provided by first wall 1 for each unit. The high-thixotropic material has an adhesive to hold the lens, respectively the meta-lens 11.

FIG. 6E shows a further exemplary step S5 of a method according to a fourth example of the present invention. FIG. 6E shows the step of scattering into single optoelectronic devices D or single optoelectronic packages indicated by vertical lines.

FIG. 6F shows a further exemplary stage of a method according to a fourth example of the present invention. FIG. 6F shows the final optoelectronic device D or package after separation step 5.

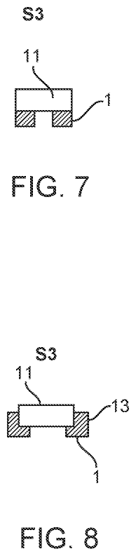

FIG. 7 illustrates an exemplary step S3 of manufacturing whereby an optical elements 11 can be positioned on a first wall 1 whereby the outside surfaces of the optical element 11 are attached flush with the outside surface of the first wall 1.

FIG. 8 illustrates an alternative of a lens holder design in comparison to the one of FIG. 7. FIG. 8 shows the embodiment with first wall 1 comprises a structure at an open end side respectively comprises a rising 13. Accordingly, an optical element 11 has to be fixed applying a second wall 2 taking into account gaps and empty spaces.

The third and the fourth example of a method according to the present invention were described showing a lens holder design according to FIG. 7. As an alternative, lens holder design according to FIG. 8 can also be used.

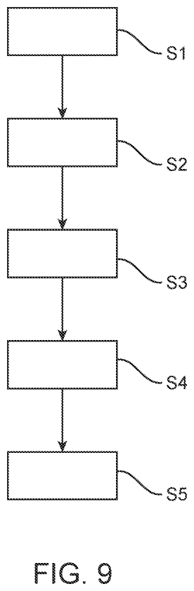

FIG. 9 illustrates a method according to another example of the present invention. FIG. 9 shows an example of the forming steps of manufacturing beginning with providing a substrate from which first walls 1 protrude along a Z-axis towards an open end side forming at least one rectangle along a X-Y-plane surrounding a respective at least one space. A second step S2 could be positioning a respective optoelectronic element 7 within the respective space and connecting it to contact pads 9. A third step could be positioning a respective optic element 11, in particular a lens, at the open end side of respective first walls 1 to cover the respective space. A fourth step could be surrounding the respective optical element 11 along a X-Y-plane with a dam material forming second walls 2. A fifth step could be separating the electronic packages out of a row or an array of packages.

1. A method for obtaining at least one optoelectronic device each comprising an optoelectronic element, wherein the optoelectronic element comprises at least one of a LED, a LASER, a VCSEL, comprising the steps of:
providing a substrate from which a first wall protrude along a Z-axis towards an open end side forming at least one rectangle along a X-Y-plane surrounding at least one space;
positioning the optoelectronic element within the at least one space and connecting the optoelectronic element to contact pads;
arranging a respective optical element, in particular a lens, at the open end side of the first wall to cover the at least one space; and
forming a second wall by surrounding the respective optical element along a the X-Y-plane with a dam material;
wherein providing a substrate comprises forming the first wall, and forming the first wall comprises forming an open end side of the first wall as a flat area; and
whereby the optical element is attached flush with the first wall and the second wall is formed perpendicular to the substrate by completely surrounding the optical element and the first wall along the X-Y plane forming rectangles.

2. The method according to claim 1,
characterized by
the substrate is a Quad-Flat-No-Leads-QFN leadframe.

3. The method according to claim 2,
characterized by
the step of providing a substrate comprises pre-molding of the leadframe.

4. The method according to claim 3,
characterized by
etching the leadframe on both sides.

5. The method according to claim 1,
characterized by
the dam material is a thixotropic material, in particular a high thixotropic material, in particular silicone and/or epoxy.

6. The method according to claim 1,
characterized by
the step of forming a second wall comprises at least one of casting, jetting or molding, compression molding, transfer molding or film assisted molding of the dam material.

7. The method according to claim 1,
characterized by
the step of forming a first wall comprises forming a recess along the first wall's open end side.

8. The method according to claim 7,
characterized by
before the step of forming a recess the open end side of a first wall was formed as a flat area.

9. The method according to claim 1,
characterized by
the step of forming a first wall comprises forming a rising along the first wall's open end side.

10. The method according to claim 1,
characterized by
the step of forming a second wall comprises filling of the dam material into gaps between adjacent positioned optical elements, recesses and/or risings.

11. The method according to claim 10,
characterized by
the step of forming a second wall comprises forming of additional structures of the dam material onto a surface of an optical element surface that is averted to the substrate.

12. (canceled)

13. The method according to claim 1,
characterized by
the second wall is formed in between the optical element, the first wall and a completely surrounding third wall, in particular being pre-molded on the substrate.

14. Method The method according to claim 1,
wherein
first walls of several optoelectronic devices comprise equal thicknesses and rectangles comprise equal sizes.

15. The method according to claim 1,
characterized by
the optoelectronic element is a die.

16. The method according to claim 1,
characterized by
connecting the optoelectronic elements by wire bonding to contact pads.

17. The method according to claim 1,
characterized by
the optoelectronic element is a meta-lens or a diffractive optical element or a micro lens array or a TIR lens.

18. Method according to anyone of the preceding claims,
characterized by
dam material comprises an adhesive, in particular Epoxy or silicone.

19. The method according to claim 1,
further comprising separating optoelectronic devices out of a row or out of an array of optoelectronic devices.

20. The method according to claim 18,
characterized by
the step of separating comprise sawing.

21. An optoelectronic device comprising:
a substrate from which a first wall protrudes along a Z-axis towards an open end side forming at least one rectangle along a X-Y-plane surrounding at least one space and the first wall forming the open end side of the first wall as a flat area;
an optoelectronic element, within the at lease one space being connected to contact pads;
an optical element, in particular a lens, at the open end side of the first wall covering the at least one space;
the optical element being surrounded along the X-Y-plane with a dam material forming a second wall,
whereby the optical element is attached flush with the first wall, and the second wall is formed perpendicular to the substrate completely surrounding the optical element and the first wall along the X-Y- plane forming rectangles.

22. The optoelectronic device according to claim 21,
characterized by
the optoelectronic element comprises an emitter, and is in particular a LED, a LASER, a VCSEL.

23. The optoelectronic device according to claim 21,
characterized by
the optoelectronic element comprises a detector or sensor.

24. (canceled)

25. (canceled)
